(19) United States
(12) Patent Application Publication
(10) Pub. No.: US 2022/0020971 A1
(43) Pub. Date: Jan. 20, 2022

(54) PRINTING DEVICE, PRINTING SYSTEM, AND PRINTING METHOD

(71) Applicants: HEFEI XINSHENG OPTOELECTRONICS TECHOLOGY CO., LTD., Hefei, Anhui (CN); BOE TECHNOLOGY GROUP CO., LTD., Beijing (CN)

(72) Inventor: Minghung HSU, Beijing (CN)

(21) Appl. No.: 17/295,065

(22) PCT Filed: Jul. 3, 2020
(86) PCT No.: PCT/CN2020/100094

§ 371 Date: May 19, 2021

(30) Foreign Application Priority Data
Jul. 3, 2019 (CN) 201910596105.0

(51) Int. Cl. H01L 51/56; B41F 16/00; B41F 31/28

(52) U.S. Cl. CPC H01L 51/56; B41F 31/28; B41F 16/006

(57) ABSTRACT

A printing device includes a base, a transfer roller, a transfer portion and at least one image collector. The transfer roller includes a rotating shaft and a cylinder body. The transfer portion is disposed on an outer circumferential surface of the cylinder body. The base is configured to allow a printing plate and a substrate to be transferred to be provided thereon, and drive the printing plate or the substrate to be transferred to move, so that the printing plate or the substrate to be transferred comes in contact with the transfer portion disposed on the cylinder body, and moves synchronously with the cylinder body. The transfer portion is configured to allow a transfer pattern to be formed thereon. The image collector is disposed on the cylinder body or the base, and is configured to collect a position of the transfer pattern transferred onto the substrate to be transferred.

### CROSS-REFERENCE TO RELATED APPLICATIONS

This application is a national phase entry under 35 USC 371 of International Patent Application No. PCT/CN2020/100094, filed on Jul. 3, 2020, which claims priority to Chinese Patent Application No. 201910596105.0, filed on Jul. 3, 2019, which are incorporated herein by reference in their entirety.

### TECHNICAL FIELD

The present disclosure relates to the field of display technologies, and in particular, to a printing device, a printing system and a printing method.

### BACKGROUND

Printed organic light-emitting diode (Printed OLED for short) technology has characteristics such as high material utilization rate and high efficiency, and fine metal masks (FMMs) or other complex patterning processes are not required for printing OLEDs, so that the OLEDs are easy to manufacture in a large area, and can achieve full-color display.

### SUMMARY

In one aspect, a printing device is provided, and the printing device includes a base, a transfer roller, a transfer portion and at least one image collector. The transfer roller includes a rotating shaft and a cylinder body, and the rotating shaft is configured to drive the cylinder body to rotate about the rotating shaft. The transfer portion is disposed on an outer circumferential surface of the cylinder body. The base is configured to allow a printing plate and a substrate to be transferred to be provided thereon, and drive the printing plate or the substrate to be transferred to move, so that the printing plate or the substrate to be transferred comes in contact with the transfer portion disposed on the cylinder body, and moves synchronously with the cylinder body. The transfer portion is configured to allow a transfer pattern to be formed thereon. The image collector is disposed on the cylinder body or the base, and the image collector is configured to collect, under driving of the cylinder body or the base, a position of the transfer pattern transferred onto the substrate to be transferred.

In some embodiments, in a case where the at least one image collector includes a plurality of image collectors, the plurality of image collectors are disposed on a circumferential surface of the cylinder body, and at least two of the plurality of image collectors are spaced apart along a circumferential direction of the cylinder body.

In some embodiments, at least two of the plurality of image collectors are spaced apart along an axial direction of the cylinder body.

In some embodiments, the plurality of image collectors are divided into at least two groups, each group includes at least two image collectors, and the image collectors included in each group are spaced apart along the circumferential direction of the cylinder body. The groups of image collectors are arranged in parallel and spaced apart along the axial direction of the cylinder body. Along the axial direction of the cylinder body, a connecting line of image collectors with corresponding positions in the groups of image collectors is parallel to the axial direction of the cylinder body.

The at least one image collector includes a plurality of image collectors, the plurality of image collectors are disposed on a circumferential surface of the cylinder body, and at least two of the plurality of image collectors are spaced apart along an axial direction of the cylinder body.

In some embodiments, the at least two of the plurality of image collectors are located on two sides of the cylinder body along the axial direction of the cylinder body.

In some embodiments, at least one observation window is disposed in the cylinder body, and one image collector is disposed at each observation window. The observation window is configured such that the image collector is able to collect the position of the transfer pattern through the observation window.

In some embodiments, the at least one image collector is disposed inside the cylinder body.

In some embodiments, the cylinder body is of a hollow cylindrical structure, and the image collector is attached to an inner circumferential surface of the cylinder body.

In some embodiments, the printing device further includes at least one first alignment mark disposed on an outer surface of transfer portion disposed on the cylinder body. A number of the first alignment mark(s) is equal to a number of the image collector(s), and each first alignment mark is disposed within a viewing angle range of one image collector.

In some embodiments, the transfer portion is made of a light-transmitting material.

In some embodiments, the printing device further includes an ink sprayer. The ink sprayer is configured to spray ink on the transfer portion to form a transfer film on the transfer portion.

In some embodiments, the at least one image collector includes a plurality of image collectors, and the plurality of image collectors are disposed on the base. At least two of the plurality of image collectors are spaced apart along a movement direction of the base; and/or at least two of the plurality of image collectors are spaced apart along a width direction of the base perpendicular to a movement direction of the base.

In some embodiments, the transfer portion is of a bendable plate-like structure.

In some embodiments, the ink sprayer include a head disposed at a side face of the cylinder body or above the cylinder body.

In some embodiments, a length of the head along an axial direction of the cylinder body is in a range from 148 mm to 152 mm.

In another aspect, a printing system is provided, and the printing system includes the printing device as described above and a controller. The controller is coupled to the transfer roller, the base and the at least one image collector of the printing device. The controller is configured to obtain, according to the position of the transfer pattern collected by the at least one image collector, a first deviation value between the position of the transfer pattern and a preset position of the transfer pattern, and adjusts, according to the first deviation value, a rotation speed of the transfer roller and/or a movement speed of the base.

In yet another aspect, a printing method is provided, and the printed method is applied to the printing system as described above. The printing method includes: spraying ink on the transfer portion that is on the cylinder body of the transfer roller, and controlling the cylinder body to rotate about the rotating shaft to form a transfer film on the transfer portion, the printing plate being fixed to a first preset position on the base to complete an alignment between the printing plate and the transfer portion; controlling the base to move synchronously with the cylinder body, so that the transfer film on the transfer portion comes in contact with the printing plate to form the transfer pattern on the transfer portion, the substrate to be transferred being fixed to a second preset position on the base to complete an alignment between the substrate to be transferred and the transfer portion; and controlling the base to move synchronously with the cylinder body, so that the transfer pattern on the transfer portion comes in contact with the substrate to be transferred to the transfer pattern onto the substrate to be transferred from the transfer portion. In a transfer process, the controller obtains, according to the position, collected by the at least one image collector, of the transfer pattern transferred onto the substrate to be transferred, the first deviation value between the position of the transfer pattern and the preset position of the transfer pattern, and adjusts, according to the first deviation value, the rotation speed of the transfer roller and/or the movement speed of the base.

In some embodiments, the outer surface of the transfer portion is provided thereon with at least one first alignment mark, the substrate to be transferred is provided thereon with at least one second alignment mark. The number of the first alignment mark(s), the number of the second alignment mark(s), and the number of the image collector(s) are equal, and each first alignment mark is within the viewing angle range of one image collector. In the transfer process, the controller acquires a second deviation value between the first alignment mark and the second alignment mark corresponding to the first alignment mark through the image collector(s), and obtains the position of the transfer pattern transferred onto the substrate to be transferred according to the second deviation value.

In some embodiments, a material of the ink includes nanoparticles containing silver, and the transfer pattern is an auxiliary cathode coupled to cathode(s) in an organic light-emitting diode (OLED) display apparatus.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art can obtain other drawings according to these drawings. In addition, the accompanying drawings in the following description may be regarded as schematic diagrams, and are not limitations on actual sizes of products, actual processes of methods and actual timings of signals involved in the embodiments of the present disclosure.

FIG. 1 is a structural diagram of a printing device, in accordance with some embodiments of the present disclosure:

FIG. 2 is a structural diagram of another printing device, in accordance with some embodiments of the present disclosure;

FIG. 3 is a top view showing a structure of a substrate to be transferred, in accordance with some embodiments of the present disclosure;

FIG. 4 is a sectional structural view based on the O-O′ direction in FIG. 3;

FIG. 5 is a schematic diagram showing that an auxiliary cathode shifts in a printing process, in accordance with some embodiments of the present disclosure;

FIG. 6 is a structural diagram of yet another printing device, in accordance with some embodiments of the present disclosure;

FIG. 7A is a structural diagram of yet another printing device, in accordance with some embodiments of the present disclosure;

FIG. 7B is a structural diagram of yet another printing device, in accordance with some embodiments of the present disclosure;

FIG. 8A is a structural diagram of a transfer roller, in accordance with some embodiments of the present disclosure;

FIG. 8B is a schematic diagram showing that image collector(s) are attached to an inner circumferential surface of a cylinder body, in accordance with some embodiments of the present disclosure;

FIG. 9A is a structural diagram of yet another printing device, in accordance with some embodiments of the present disclosure;

FIG. 9B is a structural diagram of yet another printing device, in accordance with some embodiments of the present disclosure;

FIG. 10 is a structural diagram of a printing system, in accordance with some embodiments of the present disclosure; and

FIG. 11 is a flow diagram of a printing method, in accordance with some embodiments of the present disclosure.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art on a basis of the embodiments of the present disclosure shall be included in the protection scope of the present disclosure.

Unless the context requires otherwise, term “comprise” and other forms thereof such as the third-person singular form “comprises” and the present participle form “comprising” throughout the description and the claims are construed as an open and inclusive meaning, i.e., “including, but not limited to”. In the description, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments/examples in any suitable manner.

Hereinafter, terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, term “a/the plurality of” means two or more unless otherwise specified.

In the description of some embodiments, term “coupled”, “connected”, and their derivatives may be used. For example, term “connected” may be used in the description of some embodiments to indicate that two or more components are in direct physical or electrical contact with each other. For another example, term “coupled” may be used in the description of some embodiments to indicate that two or more components are in direct physical or electrical contact. However, term “coupled” or “communicatively coupled” may also mean that two or more components are not in direct contact with each other, but yet still cooperate or interact with each other. The embodiments disclosed herein are not necessarily limited to the content herein.

“A and/or B” includes the following three combinations: only A, only B, and a combination of A and B.

The use of “applicable to” or “configured to” means an open and inclusive expression, which does not exclude devices that are applicable to or configured to perform additional tasks or steps.

In the description of the present disclosure, it will be understood that orientations or positional relationships indicated by terms “center”, “upper”, “lower”, “front”, “rear”, “left”, “right”, “vertical”, “horizontal”, “top”, “bottom”, “inner”, “outer”, etc. are based on orientations or positional relationships shown in the drawings, which are merely to facilitate and simplify the description of the present disclosure, and are not to indicate or imply that the referred devices or elements must have a particular orientation, or must be constructed or operated in a particular orientation. Therefore, they should not be construed as limitations to the present disclosure. In the description of the present disclosure, “a/the plurality of” means two or more unless otherwise specified.

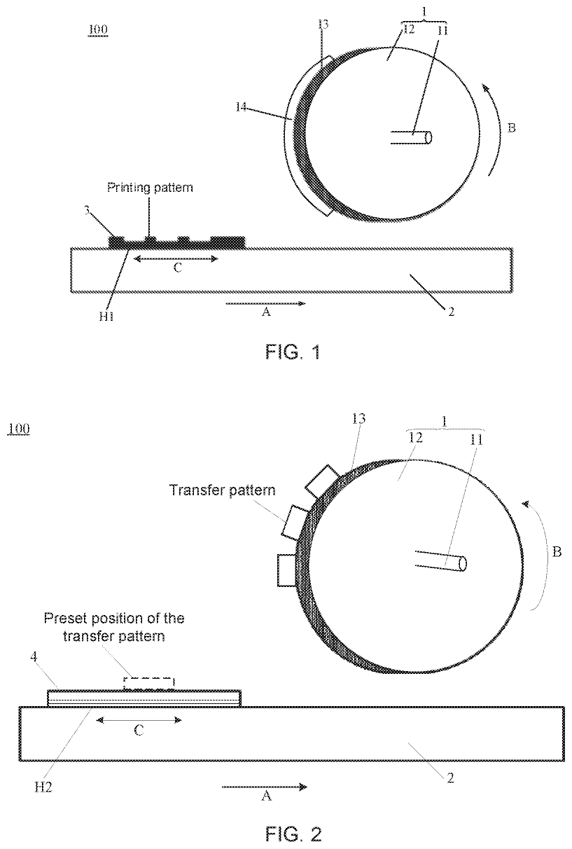

Some embodiments of the present disclosure provide a printing device. As shown in FIGS. 1 and 2, the printing device 100 includes a transfer roller 1 and a base 2.

The base 2 is configured to allow a printing plate 3 or a substrate to be transferred 4 to be provided thereon, and drive the printing plate 3 or the substrate to be transferred 4 to move. FIG. 1 shows a situation in which the printing plate 3 is provided on the base 2, and FIG. 2 shows a situation in which the substrate to be transferred 4 is provided on the base 2.

In some embodiments, the transfer roller 1 is disposed above the base 2. The base 2 is arranged horizontally, and a conveyor belt and/or a conveyor roller is provided in the base 2, so that the base 2 can drive the printing plate 3 or the substrate to be transferred 4 that is provided thereon to move in a horizontal direction.

The transfer roller 1 includes a rotating shaft 11 and a cylinder body 12, and the rotating shaft 11 is configured to drive the cylinder body 12 to rotate about the rotating shaft 11.

In some embodiments, the rotating shaft 11 may be connected to a driving shaft of a motor to use the motor to drive the rotating shaft 11 to rotate, so as to drive the cylinder body 12 sleeved on an outside of the rotating shaft 11 to rotate.

For example, the cylinder body 12 is of a hollow cylindrical structure, which may save a material of the cylinder body 12 and reduce a weight of the cylinder body 12.

For example, the cylinder body 12 may be made of a metal material, such as stainless steel.

As shown in FIGS. 1 and 2, the printing device 100 further includes a transfer portion 13 disposed on an outer circumferential surface of the cylinder body 12. Ink may be sprayed onto a surface of the transfer portion 13 to form a transfer film 14 attached onto the surface of the transfer portion 13. The formed transfer film 14 is patterned subsequently by using the printing plate 3 having a pattern, so that a transfer pattern may be formed (i.e., a forming process of the transfer pattern). After that, the transfer portion 13 is made to come in contact with a surface of the substrate to be transferred 4, and thus the transfer pattern formed on the transfer portion 13 may be transferred onto the substrate to be transferred 4, thereby realizing printing of the transfer pattern on the substrate to be transferred 4 (i.e., a transfer process of the transfer pattern).

In order to realize the formation and transfer of the transfer pattern, the printing plate 3 or the substrate to be transferred 4 is driven by the base 2 to move toward the transfer roller 1, so that the printing plate 3 or the substrate to be transferred 4 comes in contact with the transfer portion 13 disposed on the cylinder body 12, and moves synchronously with the cylinder body 12.

It will be noted that, the expression “move synchronously” refers to that when the transfer portion 13 on the cylinder body 12 is in contact with the printing plate 3 or the substrate to be transferred 4, a speed at which a contact portion of the transfer portion 13 makes a circular motion around the rotating shaft 11 is equal to or substantially equal to a speed at which the printing plate 3 or the substrate to be transferred 4 moves under the driving of the base 2, and a direction in which the contact portion of the transfer portion 13 makes the circular motion around the rotating shaft 11 and a direction in which the printing plate 3 or the substrate to be transferred 4 moves under the driving of the base 2 are the same. For example, as shown in FIGS. 1 and 2, the cylinder body 12 rotates along counterclockwise direction B, the base 2 moves along direction A, and the two move in the same moving direction and have a same speed at a contact position, which may be referred to that the cylinder body 12 and the base 2 move synchronously.

For example, the transfer portion 13 is a bendable plate-like structure, and the transfer portion 13 may be made of a light-transmitting material, such as acrylic plastic, epoxy resin, other light-transmitting materials. The transfer portion 13 may be attached to the outer circumferential surface of the cylinder body 12.

In some embodiments, as shown in FIG. 1, a surface of the printing plate 3 is uneven. Along direction C parallel to the printing plate 3, a convex pattern is the printing pattern, and a concave pattern has a same shape as the transfer pattern. In the forming process of the transfer pattern, the convex portions of the printing plate 3 come in contact with the transfer film 14 on the transfer portion 13, portions of the transfer film 14 that are in contact with the convex portions of the printing plate 3 remain on the convex portions, and portions of the transfer film 14 that are not in contact with the convex portions of the printing plate 3 remain on the transfer portion 13 to form the transfer pattern.

For example, the printing plate 3 may be made of a quartz material, and the quartz material has a characteristic of relatively great rigidity. The printing plate 3 made of the quartz material has relatively great rigidity, which is possible to reduce deformation of the printing plate 3 due to a force generated when the printing plate 3 comes in contact with the transfer portion 13. Therefore, the convex portions of the printing plate 3 are in full contact with the transfer film 14, which is conducive to remaining the portions of the transfer film 14 on the convex portions of the printing plate 3, thereby improving a printing accuracy of the printing plate 3.

In some embodiments, a structure of the substrate to be transferred 4 is described by taking an example in which an auxiliary cathode in a top-emission OLED display apparatus is printed, that is, the transfer pattern is the auxiliary cathode.

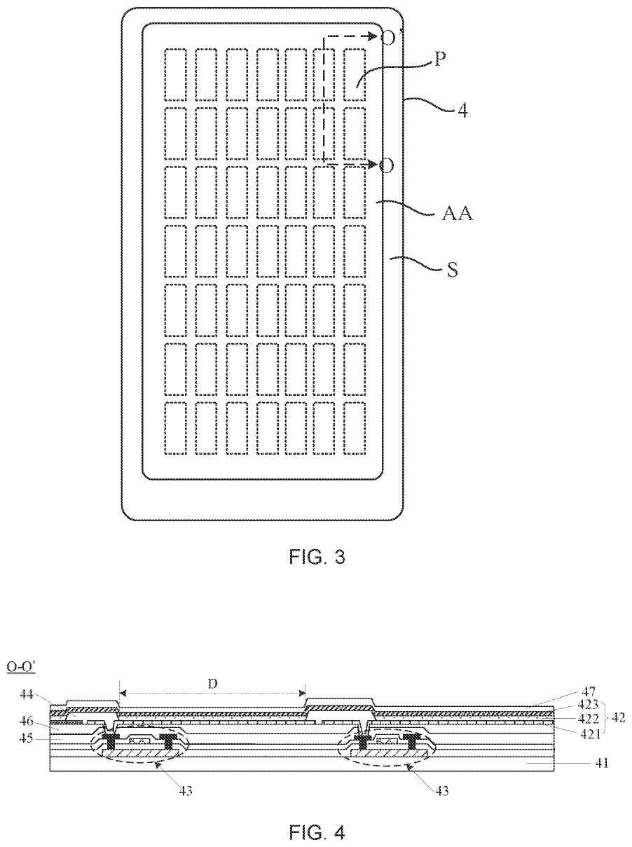

The top-emission OLED display apparatus includes the substrate to be transferred 4. As shown in FIG. 3, the substrate to be transferred 4 may include a display area AA, which is also referred to as an active area, and a peripheral region S located on a periphery of the display area AA. A plurality of sub-pixels P are provided in the display area AA. The peripheral region S is used for wiring, and may also be provided with driving circuits (e.g., a gate driving circuit).

In some embodiments, as shown in FIG. 4, the substrate to be transferred 4 includes a base 41, and pixel driving circuits and top-emission OLED devices 42 that are disposed on the base 41. The top-emission OLED device 42 includes an anode 421, a light-emitting layer 422 and a cathode 423 that are sequentially disposed at a side of the pixel driving circuit away from the base 41.

One pixel driving circuit and one top-emission OLED device 42 are included in a region where each sub-pixel P is located. The pixel driving circuit includes a plurality of thin film transistors, and at least one thin film transistor is a driving thin film transistor 43. A source or drain of the driving thin film transistor 43 is coupled to the anode 421 of the light-emitting device 42, so as to transmit a data voltage signal transmitted to the source or drain of the driving thin film transistor 43 to the anode 421 of the light-emitting device 42.

In some embodiments, as shown in FIG. 4, the substrate to be transferred 4 further includes a pixel defining layer 44. The pixel defining layer 44 includes a plurality of opening regions D, and one top-emission OLED device 42 corresponds to one opening region D, so that light exits from each opening region D.

In the substrate to be transferred 4 in the top-emission OLED display apparatus, by providing the plurality of opening regions D in the pixel defining layer 44, the top-emission OLED device 42 is arranged correspondingly to an opening region, and light emitted by the top-emission OLED device 42 is emitted from the opening region D, which improves light emission efficiency of the top-emission OLED device 42, thereby improving a display effect of the top-emission OLED display apparatus and prolonging its service life.

The anode 421 of the top-emission OLED device 42 may be opaque. For example, the anode 421 is a stacked structure of an indium tin oxide (ITO) layer, a silver (Ag) layer and another ITO layer. The cathode 423 is transparent or translucent. For example, the cathode 423 may be a film structure containing Ag nanoparticles and having a small thickness.

In some embodiments, in addition to the anode 421, the light-emitting layer 422 and the cathode 423, the top-emission OLED device 42 may further include one or more of an electron transporting layer (ETL), an electron injection layer (EIL), a hole transporting layer (HTL) and a hole injection layer (HIL). The arrangement of the EIL may improve electron injection efficiency of the top-emission OLED device 42.

In some embodiments, as shown in FIG. 4, the substrate to be transferred 4 may further include, for example, a passivation layer 45 and a planarization layer 46 that are disposed between the driving thin film transistors 43 and the anodes 421.

Based on the structure of the substrate to be transferred 4, in a case where a film layer where the cathode 423 is located has a small thickness, the cathode 423 has a large impedance, which causes a relatively large voltage drop between a voltage value of an input end of the cathode 423 and a voltage value of an output end of the cathode 423, i.e., IR-drop, thereby affecting the electron injection efficiency.

It will be noted that, a signal line used for transmitting a cathode voltage signal is provided in the substrate to be transferred 4, and the cathode 423 is coupled to the signal line, so as to receive the cathode voltage signal. In some cases, a side of the cathode 423 is coupled to the signal line. In these case, the “input end of the cathode 423” refers to the side of the cathode 423 coupled to the signal line, and the “output end of the cathode 423” refers to the other side of the cathode 423 opposite to the side of the cathode 423 coupled to the signal line.

In order to solve the above problem, in some embodiments, as shown in FIG. 4, the auxiliary cathode 47 with a relatively small impedance is formed on a side of the cathode 423 proximate to or away from the base 41 in the substrate to be transferred 4, and the auxiliary cathode 47 is coupled to the cathode 423 to form an integral electrode. An impedance of the integral electrode is less than the impedance of the cathode 423, thereby improving the electron injection efficiency. FIG. 4 shows a situation in which the auxiliary cathode 47 is disposed on the side of the cathode 423 away from the base 41.

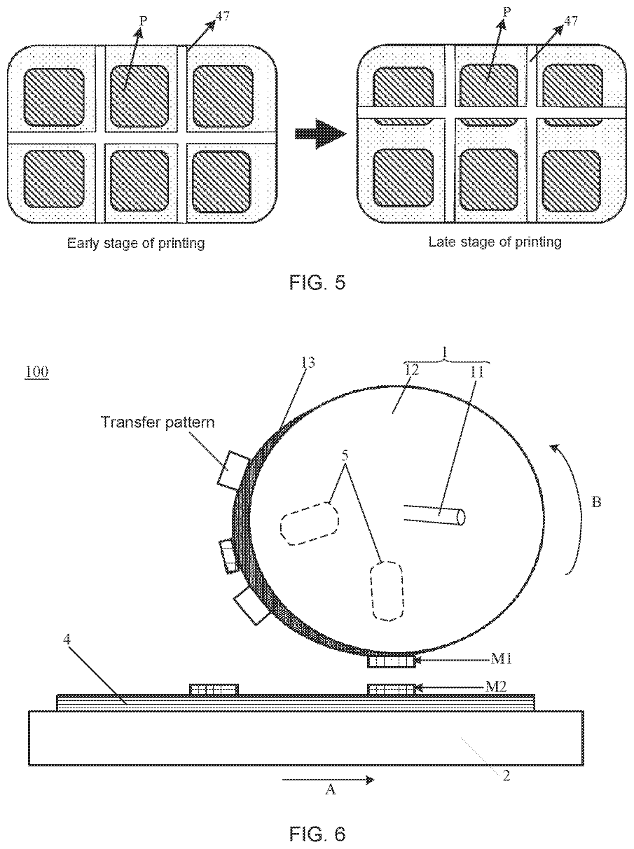

For example, as shown in FIG. 5, the auxiliary cathode 47 may be a grid of metal wires. An orthogonal projection of the auxiliary cathode 47 on the base 41 is located outside regions where the sub-pixels P are located, for example, located between any two adjacent sub-pixels P, or, located in a range of an orthogonal projection of the pixel defining layer on the base 41, so as to prevent the auxiliary cathode 47 from being provided in the plurality of opening regions D where the sub-pixels P are located, thereby avoiding affecting the light-emitting effect of the top-emission OLED devices 42.

Based on this, in a case where the printing device 100 prints the auxiliary cathode 47 on the substrate to be transferred 4, it may be implemented through the following process.

In a process of forming the transfer pattern, first, as shown in FIG. 1, the printing plate 3 formed with the printing pattern is fixed to a first preset position H1 on the base 2 to complete an alignment between the printing plate 3 and the transfer portion 13 on the cylinder body 12 of the transfer roller 1. During the spraying of the ink onto the transfer portion 13 on the cylinder body 12, the cylinder body 12 is controlled to rotate about the rotating shaft 11, so as to form the transfer film 14 on the transfer portion 13. The base 2 is controlled to drive the printing plate 3 to move synchronously with the cylinder body 12, so that the printing plate 3 comes in contact with the transfer film 14 on the transfer portion 13 disposed on the cylinder body 12, and the transfer pattern is formed on the transfer portion 13. FIG. 2 shows a structure of the transfer pattern.

Then, in a transfer process, as shown in FIG. 2, the substrate to be transferred 4 is fixed to a second preset position H2 on the base 2 to complete an alignment between the substrate to be transferred 4 and the transfer portion 13 on the cylinder body 12 of the transfer roller 1. The cylinder body 12 is controlled to rotate about the rotating shaft 11, and the base 2 is controlled to drive the substrate to be transferred 4 to move synchronously with the cylinder body 12, so that the substrate to be transferred 4 comes in contact with the transfer pattern on the transfer portion 13 disposed on the cylinder body 12, and the transfer pattern is transferred onto the substrate to be transferred 4.

As can be seen from the above two processes, in the process of forming the transfer pattern, before printing the transfer pattern, there is a need to align the printing plate 3 with the transfer portion 13 on the cylinder body 12. After that, before transferring the transfer pattern onto the substrate to be transferred 4, there is a need to align the substrate to be transferred 4 with the transfer portion 13 on the cylinder body 12. The printing pattern of the printing plate 3 is indirectly aligned with the substrate to be transferred 4 through the transfer portion 13, and after each alignment is completed, the cylinder body 12 moves synchronously with the base 2. Therefore, an alignment effect between the printing pattern of the printing plate 3 and the substrate to be transferred 4 depends on a movement accuracy of the synchronous movement described above. That is, a position accuracy of the transfer pattern transferred onto the substrate to be transferred 4 depends on the movement accuracy of the synchronous movement described above.

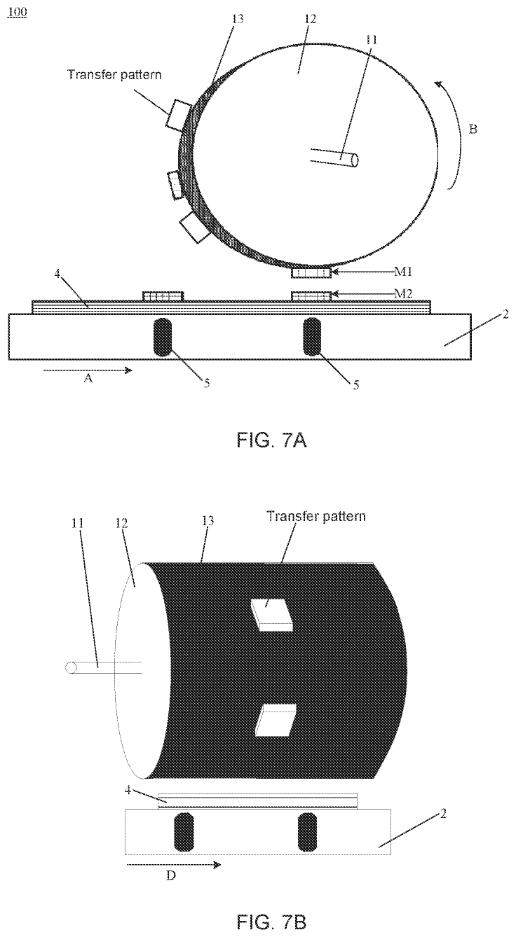

Based on this, as shown in FIGS. 6, 7A and 7B, the printing device 100 further includes at least one image collector 5 disposed on the cylinder body 12 or the base 2. The image collector(s) 5 are configured to collect, under driving of the cylinder body 12 or the base 2, a position of the transfer pattern transferred onto the substrate to be transferred 4.

If no image collector 5 is provided, in the process of transferring the transfer pattern formed on the transfer portion 13 that is on the cylinder body 12 onto the substrate to be transferred 4, the substrate to be transferred 4 is aligned once with the cylinder body 12 at an initial stage, and when an error occurs on movement speeds of the cylinder body 12 and the substrate to be transferred 4, the error will accumulate at a late stage of printing.

For example, as shown in FIG. 5, at an early stage of printing the auxiliary cathode 47, an error of the movement accuracy of the synchronous movement of the cylinder body 12 and the base 2 is within an allowable range. As the error of the movement accuracy accumulates at the late stage of printing, the auxiliary cathode 47 at the late stage of printing is printed in regions where sub-pixels P are located, thereby resulting in poor transfer.

In the printing device 100 provided in the embodiments of the present disclosure, the image collector(s) 5 are provided in the printing device 100. During the synchronous movement of the cylinder body 12 and the base 2, the position of the transfer pattern transferred onto the substrate to be transferred 4 is collected through the image collector(s) 5. In addition, by comparing, through a controller or processor, the position of the transfer pattern actually transferred onto the substrate to be transferred 4 with a preset position of the transfer pattern to be formed on the substrate to be transferred 4, it is possible to obtain a first deviation value of the position of the transfer pattern actually transferred onto the substrate to be transferred 4 relative to the preset position of the transfer pattern. Further, the movement speed of the cylinder body 12 and/or the base 2 may be adjusted in time according to the first deviation value. In this way, it is possible to improve the movement accuracy of the cylinder body 12 and the base 2, thereby avoiding occurrence of poor transfer.

In addition, in the related art, at an initial stage of forming the transfer pattern, the printing plate 3 is fixed to the first preset position H1 on the base 2 to complete the alignment between the printing plate 3 and the cylinder body 12. At an initial stage of transferring the transfer pattern formed on the transfer portion 13 that is on the cylinder body 12 onto the substrate to be transferred 4, the substrate to be transferred 4 is fixed to the second preset position H2 of the base 2 to complete the alignment between the substrate to be transferred 4 and the transfer portion 13 on the cylinder body 12. Throughout this process, the position of the transfer portion 13 on the cylinder body 12 is taken as a reference, and by fixing positions of the printing plate 3 and the substrate to be transferred 4, the alignment between the transfer pattern and the substrate to be transferred is realized. This process is an indirect alignment.

Different from the alignment manner described above, in the embodiments of the present disclosure, the position of the transfer pattern transferred onto the substrate to be transferred 4 is directly collected through the image collector(s) 5, which can realize a direct alignment between the transfer pattern and the substrate to be transferred 4. As a result, the alignment accuracy is relatively high.

In some embodiments, as shown in FIGS. 7A and 7B, the printing device 100 includes a plurality of image collectors 5, and the plurality of image collectors 5 are disposed on the base 2.

For example, as shown in FIG. 7A, at least two of the plurality of image collectors 5 are spaced apart along the movement direction A of the base 2, so that the image collectors 5 collect positions of different portions, arranged in the movement direction A of the base 2, of the transfer pattern on the substrate to be transferred 4, thereby determining the position of the transfer pattern in the movement direction A of the base 2 accurately. For example, two of the plurality of image collectors 5 are spaced apart along the movement direction A of the base 2.

For example, as shown in FIG. 7B, at least two of the plurality of image collectors 5 are spaced apart on the base 2 along a width direction D of the base 2 (i.e., a direction perpendicular to the movement direction A of the base 2), so that the image collectors 5 collect positions of different portions, arranged in the width direction of the base 2, of the transfer pattern on the substrate to be transferred 4, thereby determining the position of the transfer pattern in the width direction of the base 2 accurately. For example, two of the plurality of image collectors 5 are spaced apart along the width direction D of the base 2; and further, the two image collectors 5 are arranged on two side faces of the base 2 along the width direction of the base 2, respectively.

For example, the printing device 100 includes four image collectors 5 that are divided into two groups, and each group includes two image collectors 5. The two image collectors 5 included in each group are spaced apart along the width direction of the base 2, and are located on two side faces of the base 2 along the width direction of the base 2. The two groups of image collectors 5 are spaced apart along the movement direction A of the base 2. In this way, by setting positions of the four image collectors 5, the four image collectors 5 collect positions of specific portions of the transfer pattern on the substrate to be transferred 4, which may accurately determine the positions of the transfer pattern in the movement direction A of the base 2 and in the width direction of the base 2.

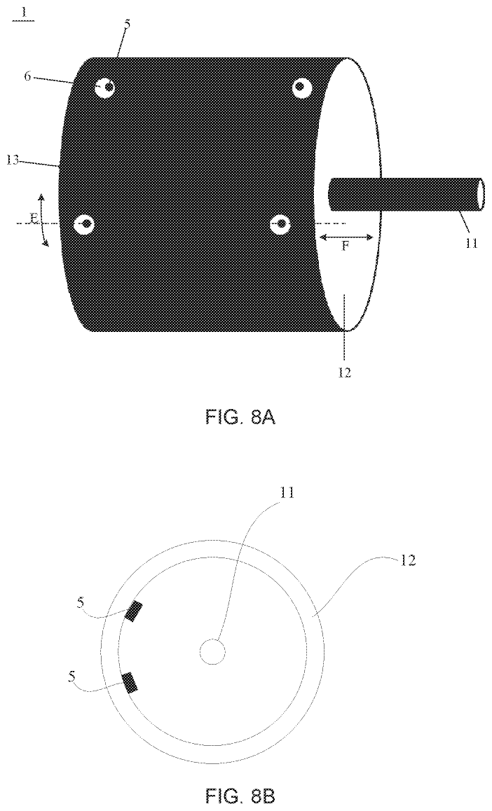

In some embodiments, as shown in FIGS. 6 and 8A, the printing device 100 includes a plurality of image collectors 5, and the plurality of image collectors 5 are disposed on the cylinder body 12.

For example, as shown in FIG. 8A, at least two of the plurality of image collectors 5 are spaced apart along a circumferential direction E of the cylinder body 12, so that the image collectors 5 collect positions of different portions, arranged in the movement direction A of the base 2, of the transfer pattern on the substrate to be transferred 4, and thereby the position of the transfer pattern in the movement direction A of the base 2 may be determined accurately. For example, two of the plurality of image collectors 5 are spaced apart along the circumferential direction E of the cylinder body 12.

For example, as shown in FIG. 8A, at least two of the plurality of image collectors 5 are spaced apart on the cylinder body 12 along an axial direction F of the cylinder body 12, so that the image collectors 5 collect the positions of different portions, arranged in the axial direction F of the cylinder body 12, of the transfer pattern on the substrate to be transferred 4, thereby determining the position of the transfer pattern in the axial direction F of the cylinder body 12 accurately. For example, two of the plurality of image collectors 5 are spaced apart along the axial direction F of the cylinder body 12; and further, the two image collectors 5 are respectively arranged on two sides of the outer circumferential surface of the cylinder body 12 along the axial direction F of the cylinder body 12.

For example, as shown in FIG. 8A, the printing device 100 includes four image collectors 5 that are divided into two groups, and each group includes two image collectors 5. The two image collectors 5 included in each group are spaced apart along the circumferential direction E of the cylinder body 12. The two groups of image collectors 5 are arranged in parallel, spaced apart along the axial direction F of the cylinder body 12, and are respectively located on two sides of the outer circumferential surface of the cylinder body 12 along the axial direction F of the cylinder body 12. In this way, by setting the positions of four image collectors 5, the four image collectors 5 collect positions of specific portions of the transfer pattern on the substrate to be transferred 4, which may accurately determine the positions of the transfer pattern in the movement direction A of the base 2 and in the axial direction F of the cylinder body 12.

For example, along the circumferential direction E of the cylinder body 12, a distance between any two adjacent image collectors 5 included in each group is equal. In a case where the cylinder body 12 rotates at a constant speed, in the group, after one image collector 5 collects an image, a next image collector 5 adjacent thereto can collect an image in a fixed and same cycle. Based on the above principle, along the movement direction A of the base 2, a distance between two adjacent portions of the transfer pattern that are collected by the image collectors 5 is equal.

For example, along the axial direction F of the cylinder body 12, a connecting line of image collectors 5 with corresponding positions in the groups of image collectors 5 is parallel to or substantially parallel to the axial direction F of the cylinder body 12, so that in the axial direction F of the cylinder body 12, the image collectors 5 collect positions of different portions of the transfer pattern on the substrate to be transferred 4.

In some embodiments, at least two of the plurality of image collectors 5 are located on two sides of the cylinder body 12 along the axial direction of the cylinder body 12, so that in the axial direction F of the cylinder body 12, the image collectors 5 collect positions of two sides of the transfer pattern on the substrate to be transferred 4.

In some embodiments, as shown in FIG. 6, one of the plurality of image collectors 5 is disposed at a position of a starting end of the transfer portion 13 on the cylinder body 12. By providing the image collector 5 at the position of the starting end of the transfer portion 13 on the cylinder body 12, it is possible that, at the initial stage of transferring the printing pattern of the printing plate 3 onto the transfer portion 13 on the cylinder body 12, positions of starting ends of the transfer portion 13 on the cylinder body 12 and the printing pattern of the printing plate 3 are collected through the image collector 5 disposed at the starting end of the transfer portion 13 on the cylinder body 12, which realizes the alignment between the transfer portion 13 on the cylinder body 12 and the printing plate 3. Moreover, it is possible that, at the initial stage of transferring the transfer pattern formed on the transfer portion 13 onto the substrate to be transferred 4, a position of a starting end of the transfer pattern actually transferred onto the substrate to be transferred 4 is collected through the image collector 5 disposed at the starting end of the transfer portion 13 on the cylinder body 12, which realizes the accurate alignment between the transfer portion 13 on the cylinder body 12 and the substrate to be transferred 4.

In some embodiments, as shown in FIG. 8A, at least one observation window 6 is provided in the cylinder body 12, and one image collector 5 is disposed at each observation window 6. The observation window 6 is configured such that the image collector 5 can collect a position of the transfer pattern through the observation window 6.

For example, the cylinder body 12 is of a hollow structure, and at least one observation window 6 is provided in the outer circumferential surface of the cylinder body 12. The observation window 6 may be a via hole that extends through a cylindrical wall of the cylinder body 12, and a light-transmitting spacer may be further provided at the via hole. The spacer may be arranged on a side of the via hole proximate to the outside of the cylinder body 12, or, on a side of the via hole proximate to the inside of the cylinder body 12. Or, the spacer may be arranged in the via hole. In this way, space can be saved. Furthermore, the spacer can prevent ink from being sprayed on the image collector 5, thereby avoiding affecting a detection result.

For example, a material of the spacer may include a transparent resin material, so that the image collector 5 can collect images through the observation window 6.

For example, the image collector 5 is disposed inside the cylinder body 12, which may utilize internal space of the cylinder body 12 reasonably, so as to reduce space occupied by the image collector 5.

For example, as shown in FIG. 8B, the image collector 5 may be attached to an inner circumferential surface of the cylinder body 12, so as to realize fixed installation of the image collector 5.

In some embodiments, as shown in FIGS. 6 and 7A, the printing device 100 further includes at least one first alignment mark M1 disposed on an outer surface of the transfer portion 13. The number of first alignment mark(s) M1 is equal to the number of image collector(s) 5, and each first alignment mark M1 is disposed within a viewing angle range of one image collector 5.

Accordingly, in some embodiments, at least one second alignment mark M2 is provided on the substrate to be transferred 4, and the number of first alignment mark(s) M1, the number of second alignment mark(s) M2, and the number of image collector(s) 5 are equal.

Based on the above arrangement, in the transfer process, the image collector 5 collect positions of the first alignment mark M1 and the second alignment mark M2 corresponding to the first alignment mark M1, so that a second deviation value between the first alignment mark M1 and the second alignment mark M2 corresponding to the first alignment mark M1 is obtained, and thereby the position of the transfer pattern transferred onto the substrate to be transferred 4 is obtained according to the second deviation value.

It will be noted that, “the second alignment mark M2 corresponding to the first alignment mark M1” refers to, in the transfer process, a second alignment mark M2 that is closest to the first alignment mark M1 along the movement direction A of the base 2.

For example, the first alignment mark M1 and the second alignment mark M2 may be of a grid-shaped structure, such as a metal mesh, which facilitates the collection of the positions of the first alignment mark M1 and the second alignment mark M2.

For example, the first alignment mark M1 is located on the transfer portion 13.

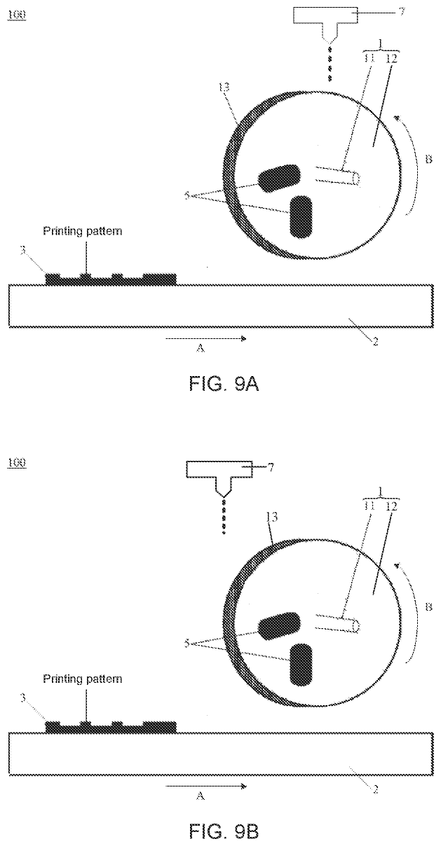

In some embodiments, as shown in FIGS. 9A and 9B, the printing device 100 further includes an ink sprayer 7, and the ink sprayer 7 is configured to spray ink on the transfer portion 13 to form a transfer film 14 on the transfer portion 13.

For example, the ink sprayer 7 may include a head disposed at a side face of the cylinder body 12 (shown in FIG. 9B) or above the cylinder body 12 (shown in FIG. 9A), and a length of the head along the axial direction F of the cylinder body 12 may be set appropriately according to a width of the transfer pattern.

For example, the length of the head along the axial direction F of the cylinder body 12 may be in a range from 148 mm to 152 mm. For example, the length of the head is 148 mm, 150 mm, or 152 mm.

It will be noted that, in a process of printing the auxiliary cathode 47, a height difference between the head and the cylinder body 12, a rotation speed of the cylinder body 12, and ink discharging and storage capacity will affect a thickness of the auxiliary cathode 47. Therefore, the thickness of the auxiliary cathode 47 may be adjusted by adjusting one or more parameters of the height difference between the head and the cylinder body 12, the rotation speed of the cylinder body 12, and the ink discharging and storage capacity.

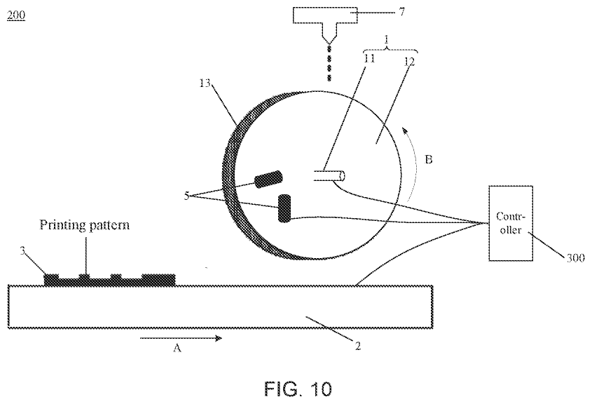

As shown in FIG. 10, embodiments of the present disclosure further provide a printing system 200, which includes the printing device 100 described above and a controller 300. The controller 300 is coupled to the transfer roller 1, the base 2 and the at least one image collector 5 of the printing device 100. The controller 300 is configured to obtain, according to the position of the transfer pattern collected by the at least one image collector 5, a first deviation value between the position of the transfer pattern and a preset position of the transfer pattern, and adjust a rotation speed of the cylinder body 12 and/or a movement speed of the base 2.

In the printing system 200 provided by the embodiments of the present disclosure, the image collector(s) 5 in the printing device 100 collect the position of the transfer pattern transferred onto the substrate to be transferred 4, and the controller 300 in the printing system 200 calculates, according to the position of the collected transfer pattern, the first deviation value of the position relative to the preset position of the transfer pattern, and further adjusts, according to the first deviation value, the rotation speed of the cylinder body 12 and/or the movement speed of the base 2. In this way, it is possible to improve the movement accuracy of the cylinder body 12 and the base 2, prevent poor transfer from occurring, and ensure a printing accuracy of the printing system 200. In addition, it is possible to realize the direct alignment between the transfer pattern and the substrate to be transferred 4, realizing a higher alignment accuracy.

In some embodiments, adjusting, by the controller 300, the rotation speed of the cylinder body 12 and/or the movement speed of the base 2 may include: calculating, by the controller 300, according to the first deviation value obtained through calculation, a correction value of a relative error between the rotation speed of the cylinder body 12 and the movement speed of the base 2; and transmitting, by the controller 300, the correction value to a movement system used for controlling the rotation speed of the cylinder body 12 to adjust the rotation speed of the cylinder body 12; or transmitting, by the controller 300, the correction value to a movement system used for controlling the movement speed of the base 2 to adjust the movement speed of the base 2; or transmitting, by the controller 300, the correction value to the movement system used for controlling the rotation speed of the cylinder body 12 and the movement system used for controlling the movement speed of the base 2 to adjust the rotation speed of the cylinder body 12 and the movement speed of the base 2 simultaneously. The expression “adjusting” the speed may include adjusting the speed to be higher or lower. The movement system used for controlling the rotation speed of the cylinder body 12 and the movement system used for controlling the movement speed of the base 2 may be a same movement system.

The controller 300 may be a central processing unit (CPU), or may be other general-purpose processors, a digital signal processor (DSP), an application-specific integrated circuit (ASIC), a field programmable gate array (FPGA), or other programmable logic devices, a discrete gate or transistor logic device, a discrete hardware component, etc. The general-purpose processor may be a microprocessor or any conventional processor.

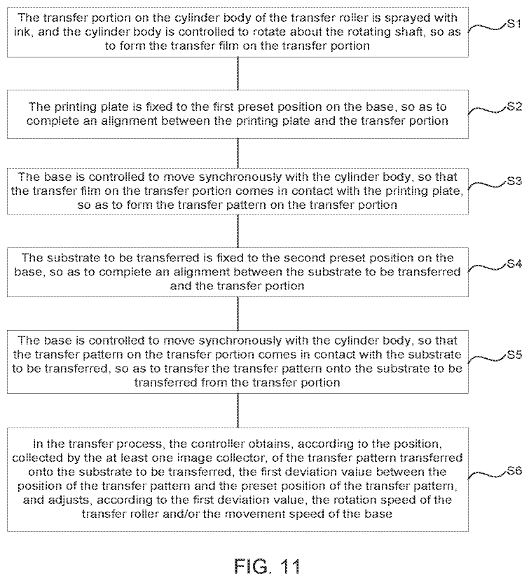

Embodiments of the present disclosure further provide a printing method that is applied to the printing system 200 as described above. As shown in FIG. 11, the printing method includes S1 to S6.

In S1, the transfer portion 13 on the cylinder body 12 of the transfer roller 1 is sprayed with ink, and the cylinder body 12 is controlled to rotate about the rotating shaft 11, so as to form the transfer film 14 on the transfer portion 13.

For example, an ink sprayer 7 may be used to spray ink on the transfer portion 13 on the cylinder body 12, and at the same time, the cylinder body 12 is controlled to rotate about the rotating shaft 11, so as to form the transfer film 14 on the transfer portion 13.

For example, a material of the ink may include nanoparticles containing silver, or other nanoparticles containing silver or silver alloy.

In S2, the printing plate 3 is fixed to the first preset position H1 on the base 2, so as to complete an alignment between the printing plate 3 and the transfer portion 13.

For example, positions of the printing plate 3 and the transfer portion 13 on the cylinder body 12 may be collected by the image collector(s) 5 disposed on the cylinder body 12 or the base 2 to obtain a position deviation between the printing plate 3 and the transfer portion 13, and the printing plate 3 is aligned with the transfer portion 13 on the cylinder body 12 to ensure a position accuracy of the transfer pattern to be formed subsequently on the transfer portion 13.

In S3, the base 2 is controlled to move synchronously with the cylinder body 12, so that the transfer film 14 on the transfer portion 13 comes in contact with the printing plate 3, so as to form the transfer pattern on the transfer portion 13.

For example, as shown in FIGS. 9A and 9B, a printing pattern is formed in the printing plate 3. By spraying ink on the transfer portion 13 of the cylinder body 12, and controlling the base 2 to drive the printing plate 3 to move synchronously with the cylinder body 12, the printing pattern of the printing plate 3 comes in contact with the transfer film 14 on the transfer portion 13, so that portions of the transfer film 14 that are in contact with the printing pattern of the printing plate 3 remain on the convex portions, and portions of the transfer film 14 that are not in contact with the printing pattern of the printing plate 3 remain on the transfer portion 13, so as to form the transfer pattern.

For example, the transfer pattern may be an auxiliary cathode 47 coupled to cathode(s) in an OLED display apparatus.

In S4, the substrate to be transferred 4 is fixed to the second preset position H2 on the base 2, so as to complete an alignment between the substrate to be transferred 4 and the transfer portion 13.

In some embodiments, positions of the substrate to be transferred 4 and the transfer portion 13 may be collected by the image collector(s) 5 disposed on the cylinder body 12 or the base 2 to obtain a position deviation between the substrate to be transferred 4 and the transfer portion 13, and the substrate to be transferred 4 is aligned with the transfer portion 14 of the cylinder body 12 to ensure a transfer accuracy.

For example, as shown in FIGS. 6 and 7A, at least one first alignment mark M1 is provided on the outer surface of the transfer portion 13, and at least one second alignment mark M2 is provided on the substrate to be transferred 4. The number of first alignment mark(s) M1, the number of second alignment mark(s) M2, and the number of image collector(s) 5 are equal, and each first alignment mark M1 is located within a viewing angle range of one image collector 5. In the transfer process, the controller 300 obtains a second deviation value between the first alignment mark M1 and the second alignment mark M2 corresponding to the first alignment mark M1 collected by the image collector 5, and completes the alignment between the substrate to be transferred 4 and the transfer portion 13 according to the second deviation value.

For example, the first alignment mark M1 is located on the transfer portion 13.

In S5, as shown in FIG. 6, the base 2 is controlled to move synchronously with the cylinder body 12, so that the transfer pattern on the transfer portion 13 comes in contact with the substrate to be transferred 4, so as to transfer the transfer pattern onto the substrate to be transferred 4 from the transfer portion 13. In S6, in the transfer process, the controller 300 obtains, according to the position, collected by the at least one image collector 5, of the transfer pattern transferred onto the substrate to be transferred 4, the first deviation value between the position of the transfer pattern and the preset position of the transfer pattern, and adjusts, according to the first deviation value, the rotation speed of the transfer roller 1 and/or the movement speed of the base 2.

In the printing method provided in the embodiments of the present disclosure, the image collector(s) 5 collect the position of the transfer pattern transferred onto the substrate to be transferred 4, and the controller 300 compares the position of the transfer pattern transferred onto the substrate to be transferred 4 with the preset position of the transfer pattern to obtain the first deviation value between the position of the transfer pattern and the preset position of the transfer pattern, and adjusts the rotation speed of the transfer roller 1 and/or the movement speed of the base 2 according to the first deviation value. In this way, the movement accuracy of the cylinder body 12 and the base 2 are improved, thereby avoiding the occurrence of poor transfer.

Moreover, in the above method, the position of the transfer pattern transferred onto the substrate to be transferred 4 is collected directly through the at least one image collector 5, which can realize the direct alignment between the transfer pattern and the substrate to be transferred 4, and thus the alignment accuracy is relatively high.

The above descriptions are only specific implementations of the present disclosure, but the protection scope of the present disclosure is not limited thereto. Any changes or replacements that a person skilled in the art could readily conceive of within the technical scope of the present disclosure shall be included in the protection scope of the present disclosure. Therefore, the protection scope of the present disclosure shall be subject to the protection scope of the claims.

1. A printing device, comprising:
a base configured to allow a printing plate and a substrate to be transferred to be provided thereon;
a transfer roller including a rotating shaft and a cylinder body, the rotating shaft being configured to drive the cylinder body to rotate about the rotating shaft;
a transfer portion disposed on an outer circumferential surface of the cylinder body; the base being further configured to drive the printing plate or the substrate to be transferred to move, so that the printing plate or the substrate to be transferred comes in contact with the transfer portion disposed on the cylinder body, and moves synchronously with the cylinder body; and
at least one image collector disposed on the cylinder body or the base, wherein
the transfer portion is configured to allow a transfer pattern to be formed thereon, and the image collector is configured to collect, under driving of the cylinder body or the base, a position of the transfer pattern transferred onto the substrate to be transferred.

2. The printing device according to claim 1, wherein the at least one image collector includes a plurality of image collectors, the plurality of image collectors are disposed on a circumferential surface of the cylinder body, and at least two of the plurality of image collectors are spaced apart along a circumferential direction of the cylinder body.

3. The printing device according to claim 16, wherein the plurality of image collectors are divided into at least two groups, each group includes at least two image collectors, and the image collectors included in each group are spaced apart along the circumferential direction of the cylinder body; and
the groups of image collectors are arranged in parallel and spaced apart along the axial direction of the cylinder body; and along the axial direction of the cylinder body, a connecting line of image collectors with corresponding positions in the groups of image collectors is parallel to the axial direction of the cylinder body.

4. The printing device according to claim 15, wherein the at least two of the plurality of image collectors are located on two sides of the cylinder body along the axial direction of the cylinder body.

5. The printing device according to claim 1, wherein at least one observation window is disposed in the cylinder body, and one image collector is disposed at each observation window; and
the observation window is configured such that the image collector is able to collect the position of the transfer pattern through the observation window.

6. The printing device according to claim 5, wherein the at least one image collector is disposed inside the cylinder body.

7. The printing device according to claim 6, wherein the cylinder body is of a hollow cylindrical structure, and the image collector is attached to an inner circumferential surface of the cylinder body.

8. The printing device according to claim 1, further comprising at least one first alignment mark disposed on an outer surface of transfer portion disposed on the cylinder body, wherein
a number of the at least one first alignment mark is equal to a number of the at least one image collector, and each first alignment mark is disposed within a viewing angle range of one image collector.

9. The printing device according to claim 1, wherein the transfer portion is made of a light-transmitting material.

10. The printing device according to claim 1, further comprising an ink sprayer configured to spray ink on the transfer portion to form a transfer film on the transfer portion.

11. A printing system, comprising:
the printing device according to claim 1; and
a controller coupled to the transfer roller, the base and the at least one image collector of the printing device, wherein
the controller is configured to obtain, according to the position of the transfer pattern collected by the at least one image collector, a first deviation value between the position of the transfer pattern and a preset position of the transfer pattern, and adjust, according to the first deviation value, a rotation speed of the transfer roller and/or a movement speed of the base.

12. A printing method, applied to the printing system according to claim 11, the printing method comprising:
spraying ink on the transfer portion that is on the cylinder body of the transfer roller;
controlling the cylinder body to rotate about the rotating shaft to form a transfer film on the transfer portion, wherein
the printing plate is fixed to a first preset position on the base to complete an alignment between the printing plate and the transfer portion;
controlling the base to move synchronously with the cylinder body, so that the transfer film on the transfer portion comes in contact with the printing plate to form the transfer pattern on the transfer portion, wherein
the substrate to be transferred is fixed to a second preset position on the base to complete an alignment between the substrate to be transferred and the transfer portion; and
controlling the base to move synchronously with the cylinder body, so that the transfer pattern on the transfer portion comes in contact with the substrate to be transferred to transfer the transfer pattern onto the substrate to be transferred from the transfer portion, wherein
in a transfer process, the controller obtains, according to the position, collected by the at least one image collector, of the transfer pattern transferred onto the substrate to be transferred, the first deviation value between the position of the transfer pattern and the preset position of the transfer pattern, and adjusts, according to the first deviation value, the rotation speed of the transfer roller and/or the movement speed of the base.

13. The printing method according to claim 12, wherein the outer surface of the transfer portion is provided thereon with at least one first alignment mark, the substrate to be transferred is provided thereon with at least one second alignment mark, a number of the at least one first alignment mark, a number of the at least one second alignment mark and a number of the at least one image collector are equal, and each first alignment mark is within a viewing angle range of one image collector;
in the transfer process, the controller acquires a second deviation value between the first alignment mark and the second alignment mark corresponding to the first alignment mark through the at least one image collector, and obtains the position of the transfer pattern on the substrate to be transferred according to the second deviation value.

14. The printing method according to claim 12, wherein a material of the ink include nanoparticles containing silver, and the transfer pattern is an auxiliary cathode coupled to at least one cathode in an organic light-emitting diode (OLED) display apparatus.

15. The printing device according to claim 1, wherein the at least one image collector includes a plurality of image collectors, the plurality of image collectors are disposed on a circumferential surface of the cylinder body, and at least two of the plurality of image collectors are spaced apart along an axial direction of the cylinder body.

16. The printing device according to claim 2, wherein at least two of the plurality of image collectors are spaced apart along an axial direction of the cylinder body.

17. The printing device according to claim 1, wherein the at least one image collector includes a plurality of image collectors, and the plurality of image collectors are disposed on the base;
at least two of the plurality of image collectors are spaced apart along a movement direction of the base; and/or
at least two of the plurality of image collectors are spaced apart along a width direction of the base perpendicular to a movement direction of the base.

18. The printing device according to claim 1, wherein the transfer portion is of a bendable plate-like structure.

19. The printing device according to claim 10, wherein the ink sprayer include a head disposed at a side face of the cylinder body or above the cylinder body.

20. The printing device according to claim 19, wherein a length of the head along an axial direction of the cylinder body is in a range from 148 mm to 152 mm.
